(19) United States
(12) Patent Application Publication
(10) Pub. No.: US 2026/0314131 A1
(43) Pub. Date: Oct. 8, 2026

(54) GASOCHROMIC LIGHT-EMITTING DIODES

(71) Applicant: CreeLED, Inc., Durham, NC (US)

(72) Inventors: Thomas Celano, Cary, NC (US); F James Claire, Chapel Hill, NC (US); Tucker McFarlane, Cary, NC (US); Austin Spencer, Durham, NC (US); Joseph G. Sokol, Durham, NC (US)

(21) Appl. No.: 19/171,896

(22) Filed: Apr. 7, 2025

(51) Int. Cl. H10H 20/855; H10H 20/851

(52) U.S. Cl. CPC H10H 20/855; H10H 20/851

(57) ABSTRACT

Solid-state lighting devices including light-emitting diodes (LEDs) and more particularly gasochromic LEDs are disclosed. Gasochromic LEDs are configured to change characteristics, such as color, wavelength, and/or overall brightness of aggregate emissions, upon detection of one or more targeted gases. An exemplary LED package includes an LED chip, a lumiphoric material, and a gasochromic layer. During normal operation, aggregate emissions from the LED package include light contributions from both the LED chip and the lumiphoric material by way of wavelength conversion. When a target gas is detected by the gasochromic layer, an optical characteristic of the gasochromic layer is changed so that contributions from the lumiphoric material in aggregate emissions are reduced. This reduction provides visual detection and/or identification of exposure to one or more targeted gases.

### FIELD OF THE DISCLOSURE

The present disclosure relates to solid-state lighting devices including light-emitting diodes (LEDs), and more particularly to gasochromic LEDs.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays and lighting devices for general illumination.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to solid-state lighting devices including light-emitting diodes (LEDs), and more particularly to gasochromic LEDs. Gasochromic LEDs are configured to change characteristics, such as color, wavelength, and/or overall brightness of aggregate emissions, upon detection of one or more targeted gases. An exemplary LED package includes an LED chip, a lumiphoric material, and a gasochromic layer. During normal operation, aggregate emissions from the LED package include light contributions from both the LED chip and the lumiphoric material by way of wavelength conversion. When a target gas is detected by the gasochromic layer, an optical characteristic of the gasochromic layer is changed so that contributions from the lumiphoric material in aggregate emissions are reduced. This reduction provides visual detection and/or identification of exposure to one or more targeted gases.

In one aspect, an LED package comprises: a support structure; at least one LED chip on the support structure, the at least one LED chip configured to provide light with a first peak wavelength; a lumiphoric material on the at least one LED chip, the lumiphoric material configured to convert a portion of the light of the first peak wavelength to light of a second peak wavelength that is different than the first peak wavelength; and a gasochromic layer on the lumiphoric material, the gasochromic layer configured to reduce an amount of light of the second peak wavelength that passes through the gasochromic layer upon detection of a target gas. The LED package may further comprise a carrier positioned between the lumiphoric material and the gasochromic layer, the carrier being transparent to the light of the first peak wavelength and the light of the second peak wavelength. The LED package may further comprise a light-altering material on the support structure, the light-altering material covering at least a portion of sidewalls of the LED chip, the lumiphoric material, and the carrier, wherein the light-altering material is configured to redirect light of the first peak wavelength and the second peak wavelength toward the gasochromic layer. In certain embodiments, the light-altering material is arranged to cover at least a portion of a sidewall of the gasochromic layer. In certain embodiments, the target gas comprises hydrogen. In certain embodiments, the target gas comprises at least one of oxygen, carbon dioxide, nitric dioxide, and hydrogen sulfide. In certain embodiments, a surface of the gasochromic layer forms an exterior surface of the LED package. In certain embodiments, the gasochromic layer is directly on the lumiphoric material. The LED package may further comprise a lens on the at least one LED chip and the lumiphoric material, wherein the gasochromic layer is on an outer surface of the lens relative to the at least one LED chip. In certain embodiments, the lens forms an air cavity on the support structure, and the at least one LED chip and the lumiphoric material reside within the air cavity. The LED package may further comprise a carrier positioned on the support structure to form an air cavity over the at least one LED chip, wherein the air cavity is vented to permit air flow with an ambient environment outside the LED package, and the gasochromic layer is on a side of the carrier that faces the at least one LED chip.

In another aspect, an LED package comprises: a support structure; a first LED chip on the support structure and a first lumiphoric material on the first LED chip; a second LED chip on the support structure and a second lumiphoric material on the second LED chip; a first gasochromic layer on the first lumiphoric material; and a second gasochromic layer on the second lumiphoric material. In certain embodiments: the first LED chip and the second LED chip are configured to provide light with a first peak wavelength; the first lumiphoric material and the second lumiphoric material are configured to convert a portion of the light of the first peak wavelength to light of a second peak wavelength that is different than the first peak wavelength; and the first gasochromic layer and the second gasochromic layer are configured to reduce an amount of light of the second peak wavelength that exits the LED package upon detection of a target gas. In certain embodiments, the target gas comprises hydrogen. In certain embodiments, the target gas comprises at least one of oxygen, carbon dioxide, nitric dioxide, and hydrogen sulfide. In certain embodiments: the first LED chip and the first lumiphoric material are configured to provide a first color spectrum; the first gasochromic layer is configured to alter a portion of the first color spectrum that exits the LED package upon detection of a first target gas; the second LED chip and the second lumiphoric material are configured to provide a second color spectrum that is different than the first color spectrum; and the second gasochromic layer is configured to alter a portion of the second color spectrum that exits the LED package upon detection of a second target gas that is different than the first target gas. In certain embodiments, the first target gas comprises one of hydrogen, oxygen, carbon dioxide, nitric dioxide, or hydrogen sulfide, and the second target gas comprises a different one of hydrogen, oxygen, carbon dioxide, nitric dioxide, or hydrogen sulfide. The LED package may further comprise a light-altering material on the support structure, the light-altering material covering at least a portion of sidewalls of the first LED chip, the first lumiphoric material, the second LED chip, and the second lumiphoric material. In certain embodiments, the light-altering material is arranged to cover at least a portion of a sidewall of the first gasochromic layer and at least a portion of a sidewall of the second gasochromic layer. The LED package may further comprise: a first carrier positioned between the first LED chip and the first gasochromic layer; and a second carrier positioned between the second LED chip and the second gasochromic layer.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of an exemplary light-emitting diode (LED) package according to principles of the present disclosure.

FIG. 2 is a spectral plot for the LED package of FIG. 1 according to aspects of the present disclosure.

FIG. 3A is a cross-sectional view of the LED package of FIG. 1 during normal operation.

FIG. 3B is a cross-sectional view of the LED package of FIG. 3A upon detection of a target gas.

FIG. 4 is a cross-sectional view of an LED package similar to the LED package of FIG. 1 for embodiments where the gasochromic layer is formed on the lumiphoric material without the intervening carrier of FIG. 1.

FIG. 5 is a cross-sectional view of an LED package similar to the LED package of FIG. 1 for embodiments where the gasochromic layer is positioned on a lens of the LED package.

FIG. 6 is a cross-sectional view of an LED package similar to the LED package of FIG. 5 where an air cavity is formed between the lens and the support structure.

FIG. 7 is a cross-sectional view of an LED package similar to the LED package of FIG. 1 for multiple-chip embodiments.

FIG. 8A is a top perspective view of an LED package similar to the LED package of FIG. 6 for embodiments where the air cavity is vented.

FIG. 8B is a side view of the LED package of FIG. 8A.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs), and more particularly to gasochromic LEDs. Gasochromic LEDs are configured to change characteristics, such as color, wavelength, and/or overall brightness of aggregate emissions upon detection of one or more targeted gases. An exemplary LED package includes an LED chip, a lumiphoric material, and a gasochromic layer. During normal operation, aggregate emissions from the LED package include light contributions from both the LED chip and the lumiphoric material by way of wavelength conversion. When a target gas is detected by the gasochromic layer, an optical characteristic of the gasochromic layer is changed so that contributions from the lumiphoric material in aggregate emissions are reduced. This reduction provides visual detection and/or identification of exposure to one or more targeted gases.

Before delving into specific aspects of the present disclosure, an overview of various elements that may be included in exemplary LED packages is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

The active LED structure for a given LED chip may be configured to generate certain wavelengths of light depending on the composition of the active layer. In certain embodiments, the active LED structure is configured to generate blue light with a peak wavelength range of approximately 430 nanometers (nm) to 480 nm. In other embodiments, the active LED structure generates green light with a peak wavelength range of 500 nm to 570 nm. In other embodiments, the active LED structure generates red light with a peak wavelength range of 600 nm to 700 nm. In certain embodiments, the active LED structure may be configured to generate light that is outside the visible spectrum, including one or more portions of the ultraviolet (UV) spectrum, or one or more portions of the near infrared spectrum, and/or the infrared spectrum (e.g., 700 nm to 1000 nm). In other applications, UV LEDs may also be provided with one or more lumiphoric materials to provide LED packages with aggregated emissions having a broad spectrum and improved color quality for visible light applications.

Aspects of the present disclosure may be applicable to LED packages with a recipient lumiphoric material that converts at least a portion of light generated from one or more LED chips to a different wavelength. For example, an LED chip may be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. An LED chip or an LED chip array and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, and the like. One or more lumiphoric materials may be provided on one or more portions of an LED chip in various configurations. For example, lumiphoric materials may be provided by direct coating on one or more surfaces of an LED chip, dispersal in an encapsulant material configured to cover one or more LED chips, as part of a cover structure with a coating on one or more optical or support elements and/or being incorporated within a cover structure, such as pre-formed phosphor-in-glass or phosphor-in-silicone structures, ceramic phosphor plates, and/or single crystal phosphors. In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips.

As used herein, a layer or region of a light-emitting device may be considered to be "transparent" when at least 80% of emitted radiation that impinges on the layer or region emerges through the layer or region. Moreover, as used herein, a layer or region of an LED is considered to be "reflective" or embody a “mirror” or a "reflector" when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a variety of geometries, such as vertical geometry or lateral geometry. A vertical geometry LED chip typically includes anode and cathode connections on opposing sides or faces of the LED chip, and a wire bond is typically used for top-side electrical connections. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or element, such as a lead frame structure or a submount.

Lead frame structures are typically at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. In certain embodiments, one or more lumiphoric materials, such as phosphor particles, may be integrated or otherwise embedded within the encapsulant material.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Light-altering materials may be arranged within LED packages to reflect or otherwise redirect light from the one or more LED chips in a desired emission direction or pattern. For chip-on-board LED packages, light-altering materials may form a dam about a perimeter of an array of LED chips, and an encapsulant material may be formed to cover the LED chips and be retained by the dam. In certain embodiments, one or more lumiphoric materials, such as phosphor particles, may be integrated or otherwise embedded within the encapsulant material.

Light-altering materials may be arranged within LED packages to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

According to principles of the present disclosure, LED packages are structured as gas detectors or sensors that alert to the presence of gas leaks. One or more gasochromic layers may be incorporated within LED packages that are configured to alter a color of aggregate emissions when a gas leak is detected. For example, an exemplary LED package may include an LED chip and a recipient lumiphoric material that converts at least a portion of light generated by the LED chip to a different wavelength. During normal operation, aggregate emissions include wavelengths provided by both the LED chip and the lumiphoric material. Upon detection of a particular gas, optical characteristics of the gasochromic layer are configured to change such that decreased emissions from the lumiphoric material escape the LED package. Altered optical characteristics may include one or more of changes in emission color or wavelength and a reduction in overall brightness. Accordingly, the LED package may provide a visual indication of a gas leak by way of changes in the color spectrum of aggregate emissions.

Exemplary gasochromic layers may embody coatings, films, and/or three-dimensional structures along various surfaces of LED packages. Gasochromic layers may be configured to detect increased amounts of various gases, such as hydrogen (H₂), oxygen (O₂), carbon monoxide (CO), nitric dioxide (NO₂), and hydrogen sulfide (H₂S), among others, based on composition of the layer. For example, tungsten trioxide (WO₃) is a gasochromic material that may be configured for detection of one or more of H₂, NO₂, and H₂S, among others. Other gasochromic materials include molybdenum trioxide (MoO₃) and vanadium oxides. In certain embodiments, catalysts may be added to gasochromic layers in a variety of manners. By way of example, catalysts for gasochromic materials of WO₃ may include platinum (Pt) and/or Pt-containing materials or palladium (Pd) and/or Pd-containing materials. Gasochromic layers may include gasochromic materials intermixed with catalysts, or gasochromic layers may include a gasochromic material coated with a catalyst. In certain embodiments, gasochromic layers may be reverted back to original optical characteristics after detection of targeted gases. For example, a gasochromic layer of WO₃ configured for detection of H₂ may undergo a bleaching process in the presence of an O₂ gas to revert to its original state.

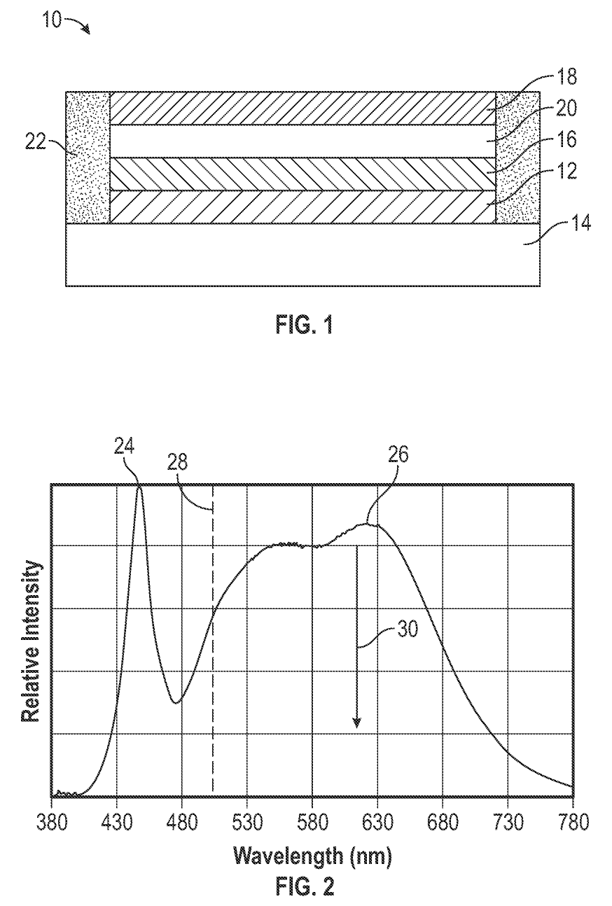

FIG. 1 is a cross-sectional view of an exemplary LED package 10 according to principles of the present disclosure. The LED package 10 includes an LED chip 12 on a support structure 14. As described above, the principles disclosed are applicable to embodiments where the support structure 14 is a submount or a lead frame structure. The LED chip 12 may be configured to generate light having a first peak wavelength, for example blue light in a range from 430 nm to 480 nm. A lumiphoric material 16, such a lumiphoric material layer, is formed on the LED chip 12 in a position configured to convert a portion of light of the first peak wavelength to a light of a second peak wavelength, such as greater than 480 nm to 700 nm. The LED package 10 further includes a gasochromic layer 18 on the lumiphoric material 16. Under normal operation, aggregate emissions for the LED package 10 include mixed light having both the first peak wavelength and the second peak wavelength that pass freely through the gasochromic layer 18. When the gasochromic layer 18 is exposed to a sufficient amount of a target gas, a reaction will occur that alters the optical property of the gasochromic layer 18 and a reduced amount of light of the second peak wavelength may pass through the gasochromic layer 18. The composition and/or amount of catalyst for the gasochromic layer 18 may be tailored to target a specific gas and/or what wavelength ranges for the second peak wavelength are reduced.

In certain embodiments, the gasochromic layer 18 may be formed on a carrier 20 that is generally transparent to light of the first and second peak wavelengths. The carrier 20 may comprise various materials, such as glass, sapphire, and/or silicone. In certain embodiments, the carrier 20 and the gasochromic layer 18 may collectively form a cover structure that is pre-formed and subsequently attached over the LED chip 12. The carrier 20 may provide a generally flat and/or smooth surface for deposition of the gasochromic layer 18. By way of example, the gasochromic layer 18 may embody one or more of sputtered nanorods, electro-spun nanofibers, and/or a multiple-layer structure with graphene, among others. In certain embodiments, the lumiphoric material 16 may also be formed on the carrier 20 on an opposite side from the gasochromic layer 18. In such embodiments, the carrier 20, the gasochromic layer 18, and the lumiphoric material 16 may collectively form the cover structure.

The LED package 10 may further include a light-altering material 22 positioned on the support structure 14 and to cover at least a portion of sidewalls of the LED chip 12 and the lumiphoric material 16. The light-altering material 22 may form a reflective layer, such as a white layer, that redirects laterally propagating light from the LED chip 12 and/or the lumiphoric material 16 toward the gasochromic layer 18. In certain embodiments, the light-altering material 22 may further cover at least a portion of sidewalls of the carrier 20 and optionally the gasochromic layer 18 in addition to the sidewalls of the LED chip 12 and the lumiphoric material 16. In any of the above-described embodiments, a top surface of the gasochromic layer 18 forms a light-emitting surface of the LED package 10. That is, the top surface of the gasochromic layer 18 is exposed to a surrounding environment for gas detection.

FIG. 2 is a spectral plot for the LED package 10 of FIG. 1 according to aspects of the present disclosure. The y-axis represents relative intensity of light in aggregate emissions and the x-axis represents wavelength. In FIG. 2, a first peak wavelength 24 corresponds to the first peak wavelength of the LED chip 12 of FIG. 1, and a second peak wavelength 26 corresponds with the second peak wavelength provided by the lumiphoric material 16 of FIG. 1. A vertical dashed line 28 in FIG. 2 is provided to delineate longer wavelengths of light that are decreased in greater quantities in aggregate emissions upon detection of a target gas by the gasochromic layer 18 of FIG. 1. The location of the vertical dashed line 28 may be tuned lower or higher based on selection of gasochromic material and/or catalyst. Under normal operation with no target gas detection, aggregate emissions may correspond to the plotted spectral curve of FIG. 2, giving the appearance of a generally white light. When a target gas is detected, the gasochromic layer 18 may reduce intensities of light for wavelengths above the vertical dashed line 28 as generally indicated by the arrow 30. Accordingly, the visible appearance of aggregate emissions may change from white to blue, thereby providing visual indication of a gas leak. Moreover, an overall brightness may be reduced for further visual indication of a gas leak.

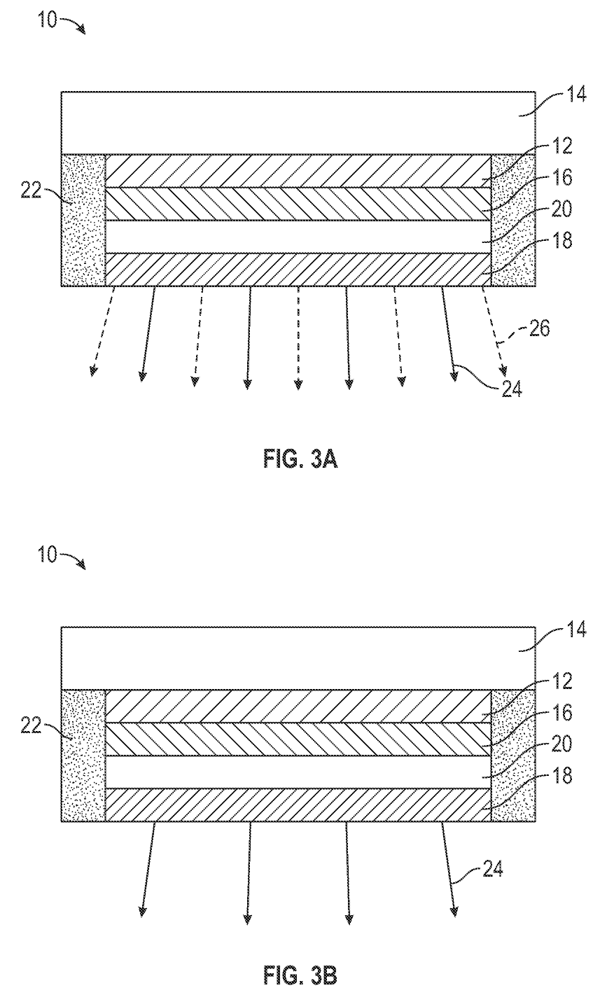

FIG. 3A is a cross-sectional view of the LED package 10 of FIG. 1 during normal operation. In this condition, no target gas is detected by the gasochromic layer 18. Accordingly, aggregate emissions exiting the LED package 10 include a mixture of light of the first peak wavelength 24 from the LED chip 12 and light of the second peak wavelength 26 from the lumiphoric material 16 to provide a generally white appearance for the aggregate emissions.

FIG. 3B is a cross-sectional view of the LED package 10 of FIG. 3A upon detection of a target gas. When the target gas causes a reaction in the gasochromic layer 18, optical characteristics of the gasochromic layer 18 change to reduce amounts of light of the second peak wavelength 26 of FIG. 3A from the lumiphoric material 16 that exit the LED package 10. Accordingly, aggregate emissions in a gas detection state may predominantly be of the first peak wavelength 24 from the LED chip 12, thereby providing visual indication of a gas leak.

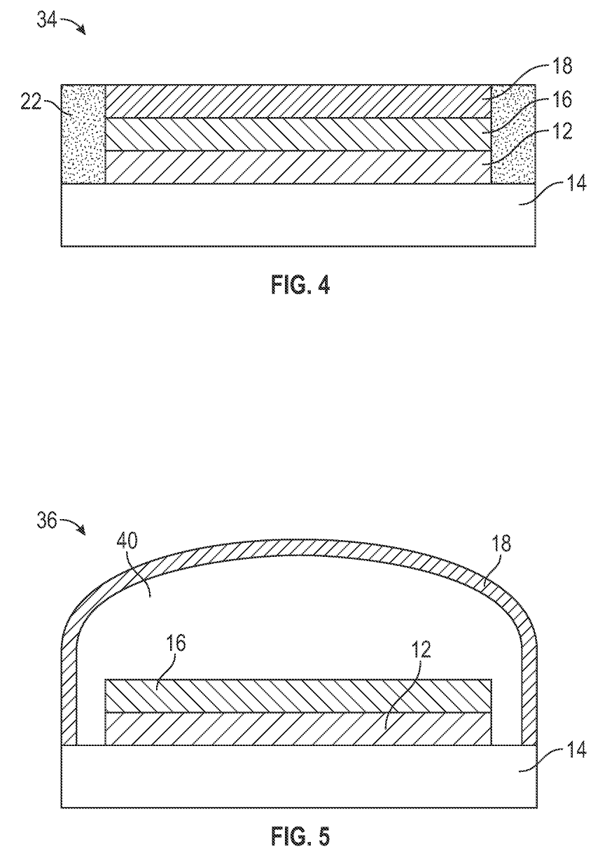

FIG. 4 is a cross-sectional view of an LED package 34 similar to the LED package 10 of FIG. 1 for embodiments where the gasochromic layer 18 is formed on the lumiphoric material 16 without the intervening carrier 20 of FIG. 1. Depending on the deposition technique for the gasochromic layer 18 and/or the structure of the lumiphoric material 16, the carrier 20 of FIG. 1 may be omitted. For example, the lumiphoric material 16 may embody a phosphor-in-glass structure with a top surface suitable for deposition of the gasochromic layer 18. In certain embodiments, the gasochromic layer 18 is directly on the lumiphoric material 16.

FIG. 5 is a cross-sectional view of an LED package 36 similar to the LED package 10 of FIG. 1 for embodiments where the gasochromic layer 18 is positioned on a lens 40 of the LED package 36. The lens 40 may comprise a shaped material that is generally transparent to light from the LED chip 12 and the lumiphoric material 16. Exemplary materials for the lens 40 include silicone or glass. In one example, the lens 40 comprises a shaped material, such as silicone, that further serves to encapsulate the LED chip 12 and the lumiphoric material 16. The lens 40 may be formed with a curved shape to direct an emission pattern of light exiting the LED package 36. For example, the lens 40 may have a shape of a dome, a hemisphere, an oval, or a bullet, among others, depending on the desired emission pattern. In certain embodiments, the gasochromic layer 18 is formed as a coating on an outer surface of the lens 40 relative to the LED chip 12 and the lumiphoric material 16.

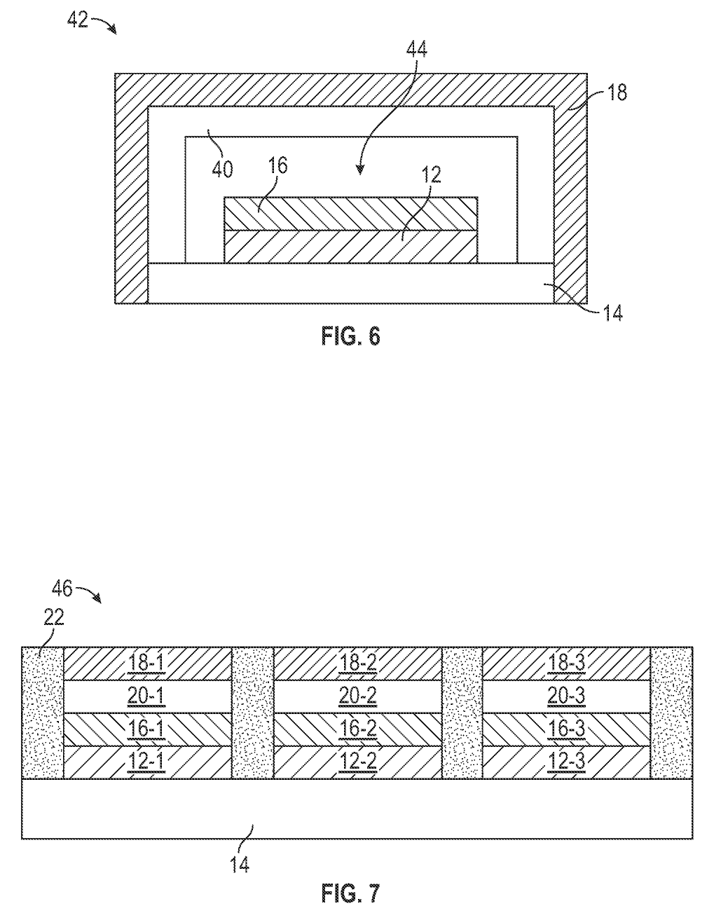

FIG. 6 is a cross-sectional view of an LED package 32 similar to the LED package 36 of FIG. 5 where an air cavity 44 is formed between the lens 40 and the support structure 14. For example, the lens 40 may embody a pre-formed structure that is subsequently attached to the support structure 14 to form the air cavity 44 therebetween. The LED chip 12 and the lumiphoric material 16 may reside within the air cavity 44. In certain embodiments, the gasochromic layer 18 may be formed on the lens 40 before the lens 40 is attached to the support structure 14. In other embodiments, the gasochromic layer 18 may be formed on the lens 40 after the lens 40 is attached to the support structure 14.

FIG. 7 is a cross-sectional view of an LED package 46 similar to the LED package 10 of FIG. 1 for multiple-chip embodiments. As illustrated by FIG. 7, multiple LED chips 12-1 to 12-3 may be mounted on the support structure 14. Each LED chip 12-1 to 12-3 includes a corresponding lumiphoric material 16-1 to 16-3, a corresponding carrier 20-1 to 20-3, and a corresponding gasochromic layer 18-1 to 18-3. In certain embodiments, each of the LED chips 12-1 to 12-3, lumiphoric materials 16-1 to 16-3, and gasochromic layers 18-1 to 18-3 have the same general structure. Accordingly, each of the LED chips 12-1 to 12-3 may be configured to generate a same or similar first peak wavelength, such as in a range from 430 nm to 480 nm, and each lumiphoric material 16-1 to 16-3 may be configured to convert a portion of light of the first peak wavelength to a light of a second peak wavelength, such as greater than 480 nm to 700 nm. Moreover, each gasochromic layer 18-1 to 18-3 may be configured to decrease higher amounts of the second peak wavelength relative to the first peak wavelength in aggregate emissions. By essentially duplicating the LED chips 12-1 to 12-3, the lumiphoric materials 16-1 to 16-3, and the gasochromic layers 18-1 to 18-3 for the LED package 46, various exposure levels of a target gas may be visually represented in aggregate emissions. For example, a small amount of target gas may cause a reaction in only the gasochromic layer 18-1 such that a visual color of aggregate emissions will shift toward the blue spectrum, such as from a generally warm white color temperature (e.g., 2700 K to 3000 K) to a generally neutral white color temperature (e.g., 3000 K to 4000 K). When an increased amount of target gas causes a reaction in the gasochromic layers 18-1 and 18-2, but not the gasochromic layer 18-3, aggregate emissions may shift to a generally cool white color temperature (e.g., 4000 K to 6500 K). Finally, when sufficient quantities of the target gas initiate a reaction in all gasochromic layers 18-1 to 18-3, aggregate emissions may generally appear blue (e.g., 430 nm to 480 nm).

With continued reference to FIG. 7, the gasochromic layers 18-1 to 18-3 may be configured to change based on different target gases. For example, the gasochromic layer 18-1 may be configured to detect H₂ gas, the gasochromic layer 18-2 may be configured to detect CO gas, and the gasochromic layer 18-3 may be configured to detect H₂S gas. In certain embodiments, peak wavelengths provided by the LED chips 12-1 to 12-3 and/or the lumiphoric materials 16-1 to 16-3 may be varied with respect to one another. In the regard, a combination of light from the LED chip 12-1 and lumiphoric material 16-1 provides a first color spectrum, a combination of light from the LED chip 12-2 and the lumiphoric material 16-2 provides a second color spectrum, and a combination of light from the LED chip 12-3 and the lumiphoric material 16-3 provides a third color spectrum, where the first, second, and third color spectrums are distinct from one another. In such a configuration, when a target gas specific to a single one of the gasochromic layers (e.g., one of 18-1 to 18-3) is detected, contributions of the corresponding lumiphoric material (e.g., one of 16-1 to 16-3) in aggregate emissions are reduced, thereby altering the specific color spectrum exiting the LED package 46. Accordingly, aggregate emissions exiting the LED package 46 may exhibit a particular color change that provides a unique visual indication of a particular detected gas. In this regard, the LED package 46 may be configured to change an overall color of aggregate emissions to one of several different colors, each of which identifies detection of a specific gas.

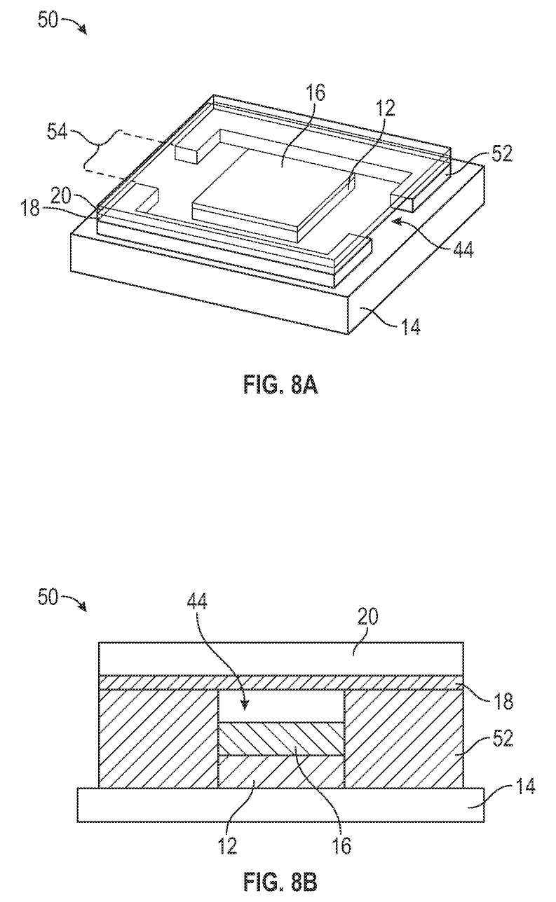

FIG. 8A is a top perspective view of an LED package 50 similar to the LED package 42 of FIG. 6 for embodiments where the air cavity 44 is vented. FIG. 8B is a side view of the LED package 50 of FIG. 8A. In certain embodiments, the air cavity 44 is open to air flow with an ambient environment outside the LED package 50. The carrier 20 may be formed in a spaced manner from the LED chip 12, thereby forming the air cavity 44 for reducing effects of heat generated by the LED chip 12 during operation. In certain embodiments, one or more spacers 52 may be positioned on the support structure 14 with a height that positions the carrier 20 above the LED chip 12 and forms the air cavity 44. The spacers 52 have a shape that forms one or more apertures 54 to permit air flow. The spacers 52 may comprise a material that is separate from the carrier 20, such as a light-altering material configured to reflect light. In other embodiments, the spacers 52 may be formed by continuous extensions of the carrier 20. In such embodiments, the gasochromic layer 18 may also be formed on a side of the spacers 52 facing the LED chip 12. In certain embodiments, the lumiphoric material 16 is positioned on the LED chip 12. Since the air cavity 44 provides air flow to the surrounding environment, the gasochromic layer 18 may be positioned on a side of the carrier 20 that faces the LED chip 12. In such an arrangement, the gasochromic layer 18 may be protected by the carrier 20 during handling of the LED package 50 while also being positioned to still receive and detect a gas leak.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a support structure;
at least one LED chip on the support structure, the at least one LED chip configured to provide light with a first peak wavelength;
a lumiphoric material on the at least one LED chip, the lumiphoric material configured to convert a portion of the light of the first peak wavelength to light of a second peak wavelength that is different than the first peak wavelength; and
a gasochromic layer on the lumiphoric material, the gasochromic layer configured to reduce an amount of light of the second peak wavelength that passes through the gasochromic layer upon detection of a target gas.

2. The LED package of claim 1, further comprising a carrier positioned between the lumiphoric material and the gasochromic layer, the carrier being transparent to the light of the first peak wavelength and the light of the second peak wavelength.

3. The LED package of claim 2, further comprising a light-altering material on the support structure, the light-altering material covering at least a portion of sidewalls of the LED chip, the lumiphoric material, and the carrier, wherein the light-altering material is configured to redirect light of the first peak wavelength and the second peak wavelength toward the gasochromic layer.

4. The LED package of claim 3, wherein the light-altering material is arranged to cover at least a portion of a sidewall of the gasochromic layer.

5. The LED package of claim 1, wherein the target gas comprises hydrogen.

6. The LED package of claim 1, wherein the target gas comprises at least one of oxygen, carbon dioxide, nitric dioxide, and hydrogen sulfide.

7. The LED package of claim 1, wherein a surface of the gasochromic layer forms an exterior surface of the LED package.

8. The LED package of claim 1, wherein the gasochromic layer is directly on the lumiphoric material.

9. The LED package of claim 1, further comprising a lens on the at least one LED chip and the lumiphoric material, wherein the gasochromic layer is on an outer surface of the lens relative to the at least one LED chip.

10. The LED package of claim 9, wherein the lens forms an air cavity on the support structure, and the at least one LED chip and the lumiphoric material reside within the air cavity.

11. The LED package of claim 1, further comprising a carrier positioned on the support structure to form an air cavity over the at least one LED chip, wherein the air cavity is vented to permit air flow with an ambient environment outside the LED package, and the gasochromic layer is on a side of the carrier that faces the at least one LED chip.

12. A light-emitting diode (LED) package comprising:
a support structure;
a first LED chip on the support structure and a first lumiphoric material on the first LED chip;
a second LED chip on the support structure and a second lumiphoric material on the second LED chip;
a first gasochromic layer on the first lumiphoric material; and
a second gasochromic layer on the second lumiphoric material.

13. The LED package of claim 12, wherein:
the first LED chip and the second LED chip are configured to provide light with a first peak wavelength;
the first lumiphoric material and the second lumiphoric material are configured to convert a portion of the light of the first peak wavelength to light of a second peak wavelength that is different than the first peak wavelength; and
the first gasochromic layer and the second gasochromic layer are configured to reduce an amount of light of the second peak wavelength that exits the LED package upon detection of a target gas.

14. The LED package of claim 13, wherein the target gas comprises hydrogen.

15. The LED package of claim 13, wherein the target gas comprises at least one of oxygen, carbon dioxide, nitric dioxide, and hydrogen sulfide.

16. The LED package of claim 12, wherein:
the first LED chip and the first lumiphoric material are configured to provide a first color spectrum;
the first gasochromic layer is configured to alter a portion of the first color spectrum that exits the LED package upon detection of a first target gas;
the second LED chip and the second lumiphoric material are configured to provide a second color spectrum that is different than the first color spectrum; and
the second gasochromic layer is configured to alter a portion of the second color spectrum that exits the LED package upon detection of a second target gas that is different than the first target gas.

17. The LED package of claim 16, wherein the first target gas comprises one of hydrogen, oxygen, carbon dioxide, nitric dioxide, or hydrogen sulfide, and the second target gas comprises a different one of hydrogen, oxygen, carbon dioxide, nitric dioxide, or hydrogen sulfide.

18. The LED package of claim 12, further comprising a light-altering material on the support structure, the light-altering material covering at least a portion of sidewalls of the first LED chip, the first lumiphoric material, the second LED chip, and the second lumiphoric material.

19. The LED package of claim 18, wherein the light-altering material is arranged to cover at least a portion of a sidewall of the first gasochromic layer and at least a portion of a sidewall of the second gasochromic layer.

20. The LED package of claim 12, further comprising:
a first carrier positioned between the first LED chip and the first gasochromic layer; and
a second carrier positioned between the second LED chip and the second gasochromic layer.
